(19) United States
(12) Patent Application Publication
(10) Pub. No.: US 2022/0299562 A1
(43) Pub. Date: Sep. 22, 2022

(54) ELECTRIC CHARACTERISATION OF A MATRIX ADDRESSING CIRCUIT

(71) Applicant: COMMISSARIAT A L'ENERGIE ATOMIQUE ET AUX ENERGIES ALTERNATIVES, Paris (FR)

(72) Inventors: Aurélien SUHM, Grenoble Cedex 09 (FR); Gwenaël LE RHUN, Grenoble Cedex 09 (FR); Nicolas DEVANCIARD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/693,688

(22) Filed: Mar. 14, 2022

(30) Foreign Application Priority Data
Mar. 16, 2021 (FR) 21 02571

(51) Int. Cl. G01R 31/28; G09G 3/00

(52) U.S. Cl. CPC G01R 31/2837; G09G 3/006

(57) ABSTRACT

A structure for the testing of an electronic circuit for addressing a matrix of cells including a plurality of blocks containing at least one first material, piezoelectric and/or dielectric, the dielectric properties of which can be modulated according to the intensity of an electric field that is applied to it, at least one separation region between the blocks, the structure further including a shared electrode connected to a first end of the blocks containing the first material, a second end of the blocks containing the first material being arranged with respect to a face of the structure called “contact face”, so that when the contact face is disposed on the addressing circuit, the second end of the blocks is connected to at least one conductive stud of the addressing circuit.

### TECHNICAL FIELD

The present invention lies in the field of electric testing to verify the functionality and/or characterise an electronic circuit, also called “addressing” circuit, for controlling the cells of a matrix of cells and applies in particular to the testing of addressing circuits of matrices, such as micro-screens, the cells of which are pixels or display elements for example of the liquid crystal or LED (light-emitting diode) type made of organic material or made of III-N material.

It relates in particular to an improved structure for allowing to test the functionality of the elements of an electronic matrix addressing circuit as well as a test device provided with such a structure, even before the complete assembly of the matrix.

### PRIOR ART

The display devices of the micro-screen type are generally formed by a matrix of display pixels arranged and assembled on an electronic circuit for addressing the pixels, typically in the form of an ASIC (acronym for Application-Specific Integrated Circuit), allowing to modulate, according to the technology used, the voltage and/or the current of the pixels.

Electric testing devices allowing to validate the operation of such displays, determine their characteristics, or even carry out a calibration exist.

The document U.S. Pat. No. 5,546,013A presents for example a device for testing a matrix of LCD (Liquid Crystal Display) pixels controlled by TFT (“Thin-Film Transistor”) transistors. The test is carried out here by emitting test electric pulses on gate lines and data lines to which the matrix is connected.

The document U.S. Pat. No. 10,580,352 B2 provides a device for testing a matrix of micro-light-emitting diodes using probes and involves in particular analysing an image emitted by the matrix to verify its functionality.

As for the document U.S. Pat. No. 10,198,984 B2, it relates to a test device allowing to determine and calibrate the luminance of the pixels of a display device.

In general, when the testing of this type of device is carried out, in certain cases it can be difficult to conclude with certainty which part of the device is responsible for a malfunction, and in particular whether this malfunction comes from the matrix of pixels itself or from the addressing circuit that allows to individually control the pixels of this matrix.

To allow to verify a possible defect that is related to the method for manufacturing the addressing circuit, it is known to add test patterns as close as possible to the addressing circuit in order to validate that its manufacturing went well.

Nevertheless, this only partly reflects the final electric operation of each pixel or associated control element of the display device.

The problem of finding a new device for testing functionality of the elements of an addressing circuit of a matrix of cells and which is in particular improved with respect to the disadvantages mentioned above thus arises.

### DISCLOSURE OF THE INVENTION

According to one aspect, the present invention relates to a structure for the testing of an electronic circuit for addressing a matrix of cells, said electronic addressing circuit being intended to be assembled with and connected to said matrix or at least one layer of said matrix via conductive studs, said structure comprising:

a plurality of blocks containing at least one first material, piezoelectric and/or dielectric, the dielectric properties of which can be modulated according to the intensity of an electric field that is applied to it,

at least one separation region between said blocks, said at least one separation region containing at least one insulating material, said test structure further comprising:

a shared electrode connected to a first end of said blocks containing said first material,

a second end of said blocks containing said first material ending at a contact face of said structure or a conductive zone ending at said contact face so that, when said contact face of the structure is disposed in a removable manner on the addressing circuit, a second end of said blocks can be connected to at least one given conductive stud out of said conductive studs.

Such a structure can allow to carry out tests and/or measurements on an addressing circuit before the matrix of cells is added or a layer, for example a display layer having electroluminescent properties, is added onto the addressing circuit.

“Cell” means here an element or a zone of a matrix that can be controlled individually. The term cell does not therefore only designate a pixel provided with a display element. Indeed, the matrix can alternatively be formed by cells each provided with a detector, or sensor, or transducer, or emitter, or actuator element.

A test is typically carried out by applying at least one test electric signal and by detecting and/or measuring, after such a signal, possible variations, in particular in shape and/or in dielectric properties of the blocks of the structure caused by a variation in an electric field between at least one conductive stud and the shared electrode.

According to one possible embodiment, the shared electrode can rest on a substrate.

The substrate can advantageously be made from polymer material or made from rubber or made from glass.

The substrate can in particular be a substrate flexible because of its thickness and the material(s) forming it. The substrate can be provided made of a material such that the substrate has a ratio of mass density to Young's modulus (d/E) greater than 100 s²m⁻², in particular made of polymer material or made of rubber.

Advantageously, the shared electrode rests on a substrate containing a material transparent to light rays, in particular in the visible and/or infrared range.

Advantageously the shared electrode can be formed by a conductive layer transparent to light rays in particular in the visible and/or infrared range.

According to one possible embodiment of the structure, said first end of said blocks containing said first material can be coated with a conductive zone that reflects light rays in particular in the visible and/or infrared range.

Advantageously, the second material of the separation region(s) can contain polymer material and/or be provided with a Young's modulus of less than 50 GPa.

According to another aspect, the present invention relates to a device for testing an electronic addressing circuit comprising a structure as defined above connected and disposed in a removable manner on the addressing circuit. “In a removable manner” means that the structure can be removed from the addressing circuit once the test or the measurements have been carried out, and in particular by simple gripping without another treatment being necessary to carry out this removal.

Thus, an embodiment of the present invention relates to a device for testing an electronic addressing circuit of a matrix of cells, each cell comprising an element capable of being controlled via a control element of said electronic addressing circuit, said electronic addressing circuit comprising a matrix set of control elements and being provided with a first matrix arrangement of conductive studs, each control element being provided with at least one of said conductive studs, the test device comprising:

a structure as defined above, arranged, said structure being arranged in a removable manner on said addressing circuit and so that at least a first conductive stud of said first matrix set of conductive studs is connected to one or more blocks containing the first material of said structure, and so that at least a second conductive stud of said first matrix set of conductive studs is connected to one or more other blocks containing the first material of said structure.

On the scale of a control element also called “subcell” or “subpixel” of the addressing circuit, a physical value allowing to control the addressing of the cell can be tested or measured. Such a device allows to obtain a map of the operation of the addressing circuit before the technological steps allowing to finalise the matrix are carried out.

Advantageously, in said first matrix set, said conductive studs of the addressing circuit are distributed according to a first distribution spacing and wherein the blocks containing said first material are distributed according to a second matrix set with a second distribution spacing, the second distribution spacing being provided as greater than the first distribution spacing and so that each conductive stud is connected to at least one block made from the first material of said test structure. Such an arrangement can allow a positioning of the test structure without necessarily having to carry out a precise alignment of the blocks of the test structure with respect to said studs of said first matrix set.

The test device can further comprise a circuit that generates test electric signals.

This generator circuit can be connected to the shared electrode of the structure and configured to apply one or more test electric signals to the control elements of said addressing circuit.

When the first material in the structure is piezoelectric, the device can further comprise a measurement device configured to detect a deformation of said structure after at least one first test electric signal is applied to a first control element.

The measurement device can be provided with optical measurement means, for example comprising a full-field optical profilometer and/or at least one camera.

Alternatively or in combination, the test device can also comprise an electric measurement device connected to the shared electrode and to at least one first stud, and configured to measure a response electric signal to at least one first test electric signal applied to a first control element connected to the first stud.

The stud tested can be changed by changing the stud selected via the addressing circuit.

This electric measurement device can in particular be provided with a capacitance meter configured to, after the first test electric signal has been applied, measure a capacitance between said first stud and said shared electrode.

This electric measurement device can also be provided with a means for measuring current between said first stud and said electrode after the first test electric signal has been applied.

According to one possible embodiment of the test device, the circuit that generates test signals can be configured to:

apply a first potential to a first control element of the addressing circuit, then apply another potential different from the first potential to the first control element, and/or to

apply a first potential to a first control element of the addressing circuit and apply a second potential to a second control element of the addressing circuit.

According to a specific embodiment, the electronic addressing circuit can be dedicated to controlling a matrix of display elements, for example of the LCD type or of the organic LED or micro-LED type, in particular made of III-N material such as GaN.

According to another aspect, the present application relates to a method for electric testing and/or measurement comprising the use of a test device as defined above.

According to another aspect, the present application relates to a method for manufacturing a matrix device provided with a matrix of pixels, each pixel being capable of being controlled via a control element of an electronic addressing circuit, the method comprising, in this order, steps involving:

putting in place a test device as defined above, in order to test the addressing circuit,

removing said test structure from said addressing circuit, then

assembling and connecting said matrix of pixels or at least one layer of said matrix device, in particular a display layer, onto said addressing circuit.

Thus, during a method for manufacturing a micro-screen controlled by an addressing circuit of the ASIC type, after having manufactured the ASIC this ASIC is tested via a structure and a device as defined above, then one or more electro-optical layers, pixelated or not, can be assembled onto this ASIC.

### BRIEF DESCRIPTION OF THE DRAWINGS

The present invention will be better understood upon reading the description of embodiments given, purely for informational and in no way limiting purposes, in reference to the appended drawings in which:

FIG. 1 is used to illustrate an example of a structure as implemented according to an embodiment of the present invention and intended to be disposed in a removable manner on a matrix electronic addressing circuit dedicated to the control of pixels of a matrix;

FIG. 2 is used to illustrate an example of a test device as implemented according to an embodiment of the present invention in which the test structure is arranged in a temporary manner on the addressing circuit before its final assembly with a matrix of pixels or with at least one display layer;

FIG. 3 is used to illustrate an example of a device for testing control elements of a matrix electronic circuit associated with an optical device for detecting the deformations of blocks of piezoelectric material disposed on the addressing circuit and at the ends of which a test electric voltage is capable of being applied;

FIGS. 4A, 4B are used to illustrate an equivalent wiring diagram of a control element of a specific example of an addressing circuit of a liquid-crystal display and an equivalent wiring diagram of this same control element when it is associated with a test structure as implemented according to an embodiment of the present invention;

FIGS. 5 and 6 are used to illustrate a variation in capacitance of dielectric blocks of a test structure when various test voltages are applied to them;

FIG. 7 is used to illustrate an embodiment for which the testing of the addressing circuit is carried out by detection of a variation in capacitance of blocks of the test structure made of dielectric material having a dielectric constant that can be modulated;

FIG. 8 is used to illustrate a stage of a circuit, which generates test signals, configured to emit test electric signals to the various control elements of an addressing circuit, and which is co-integrated in the same circuit as the addressing circuit;

FIG. 9 is used to illustrate an assembly between a matrix of display elements and its addressing circuit once a test of functionality and/or measurements as implemented according to the invention have been carried out on the addressing circuit;

FIGS. 10A, 10B, 10C, 10D, 10E, 10F, 10G, 10H are used to illustrate an example of a method for manufacturing a test structure as implemented according to an embodiment of the present invention.

Identical, similar or equivalent parts of the various drawings carry the same numerical references so as to facilitate the passage from one drawing to the other.

### DETAILED DISCLOSURE OF SPECIFIC EMBODIMENTS

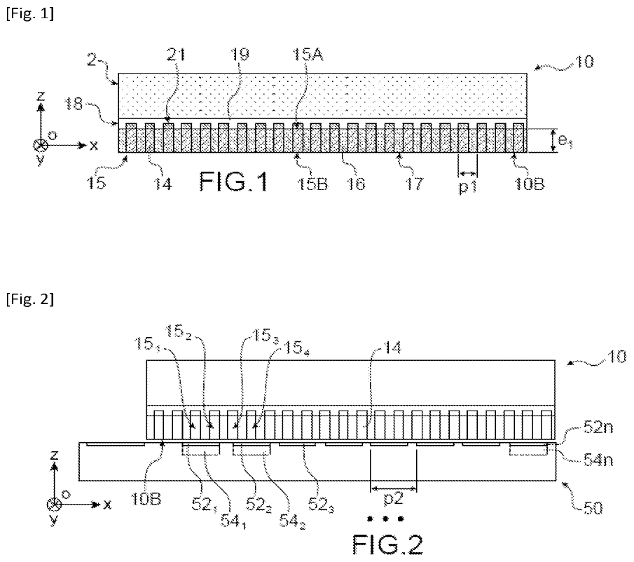

Reference is now made to FIG. 1 which gives an exemplary embodiment of a structure 10 according to the invention, to carry out a test of an electronic matrix addressing circuit (not shown in this drawing).

The electronic circuit to be tested, the functionality of which it is desired to verify and/or certain operating parameters of which it is desired to measure, allows to carry out the addressing in other words to individually control and/or activate elements also called “cells” of a matrix.

The cells of this matrix can be for example display elements, in other words display pixels, for example such as LEDs that are organic or made of III-N material or liquid-crystal displays. In this case, the matrix of display elements or at least one electro-optical display layer are intended to be assembled later onto the addressing circuit, in particular once the functionality of this addressing circuit is verified.

The test structure 10 is thus provided as removable and made to be disposed in a temporary manner on the addressing circuit to carry out a test of control elements of the latter also called “subcells”, each control element (or subcell) being associated with a cell and provided to control and/or activate this cell. In the case in which the cells are display pixels, each pixel is typically associated with several subcells (in this case called “subpixels”), each allowing to control the display of a colour. The structure 10 thus allows to verify the operation on the scale of the subpixels.

To test the addressing circuit and in particular verify the functionality of its control elements (or subcells), blocks 15 made of a piezoelectric and/or dielectric material are integrated into the structure 10.

The material of the blocks 15 is a material chosen so that its properties can be modulated according to the intensity of a test electric field that is applied to it. In the case in which the blocks 15 are made of a dielectric material, a material is chosen, the dielectric properties of which, in particular the dielectric constant, can vary according to the amplitude of an electric field that is applied to it.

In the case in which the blocks 15 are made of piezoelectric material, they can in particular contain ferroelectric or pyroelectric material.

FIG. 1 is used to illustrate a specific exemplary embodiment for which the blocks 15 are made of piezoelectric material 14. The blocks 15 are in this case capable of deforming when a suitable electric field is applied to them. The test structure 10 is thus provided with a plurality of distinct blocks 15, and each block can be made to be deformed when a test electric signal, typically a voltage, is applied to it via electrodes arranged on either side of this block 15.

The blocks 15 of piezoelectric material 14 have a thickness e₁ (measured parallel to the axis z of an orthogonal reference frame [O;x;y;z] given in FIG. 1) which can be approximately several micrometres or less, for example between 50 nm and 1 μm. This thickness e₁ is typically chosen by establishing a compromise between a level of piezoelectric coefficient d33,f routinely called required “d33”, which increases according to the thickness of the block 15, and a level of electric field that it is desired to apply to this block 15 and which decreases with the thickness.

As for the lateral dimensions (dimensions measured parallel to the plane [O; x; y]) of the blocks 15 of piezoelectric 14, they are chosen by taking into account the resolution of the conductive studs of the circuit to be tested and to which they are intended to be connected. The blocks 15 of piezoelectric 14 can have for example a width between 0.5 and 1 μm.

The blocks 15 are typically distributed according to a matrix arrangement, into at least one row and typically into several rows of distinct blocks 15. The matrix arrangement is in this case preferably provided according to that of conductive studs of the addressing circuit on which the blocks 15 of piezoelectric material 14 are made to be disposed. Preferably a spacing p₁ (distance measured parallel to the plane [O;x;y] and given in FIG. 1) of distribution of the blocks 15 of piezoelectric material smaller than that p₂ of the conductive studs of the electronic circuit to be tested is chosen. The spacing p₁ defined here as the cumulative distance of the width of a block and of the region separating two adjacent blocks 15 of piezoelectric material 14 is less than the cumulative distance between the width of a stud and the width of a zone separating two adjacent conductive studs, so that when the structure 10 is disposed against the matrix arrangement of conductive studs, a conductive stud of the electronic circuit to be tested is disposed facing and in contact with at least one block 15 of piezoelectric material. Preferably, p₁ is chosen as approximately 3 to 4 times smaller than p₂ (distance measured parallel to the plane [O; x; y] in FIGS. 1 and 2). The distance between two adjacent blocks 15 of piezoelectric material can also be chosen according to the minimum resolution in the plane of the lenses used, for example on an optical profilometer, made to measure a deformation of the piezoelectric material 14 when a test electric signal is applied to it. This choice also depends on the parameter d₃₃ of the piezoelectric material 14. For example, a distance between adjacent blocks 15 of piezoelectric material between 0.3 μm and 3.5 μm can be provided. A submicronic lateral dimension of the blocks 15 has the advantage of increasing the piezoelectric coefficient d₃₃ because of the increased mobility of the a domains, corresponding to a biasing in the plane with respect to the c domain corresponding to a polarisation outside of the plane.

The piezoelectric material 14 is preferably chosen in such a way as to have a significant piezoelectric coefficient d₃₃, that is to say greater than 50 pm/V.

The piezoelectric material 14 can be in particular a ferroelectric for example such as lead zirconate titanate (PZT), or PZT doped with lanthanum (La) or with niobium (Nb), or PMN-PT (lead magnesium niobate-lead titanate), or a piezoelectric ceramic material such as KNN (potassium sodium niobate), or a material containing bismuth like (BiₓNa_{y})TiO₃, with typically x=y=0.5 known by the acronym BNT, or BNT-BT (1-x)(Bi_{0.5}Na_{0.5})TiO₃-xBaTiO₃ with x typically between 0.05 and 0.1. The piezoelectric material 14 can also be a pyroelectric material for example such as AlN or ZnO. By adapting the composition of the piezoelectric material 14, the piezoelectric coefficient d33 can be increased if necessary. This can be carried out in particular by optimising the ratio between the a and c domains or by providing a porous piezoelectric material 14, for example porous PZT.

Between the adjacent blocks 15 of piezoelectric material, typically there is at least one space or one separation region 17 made of a material 16 different than that of the blocks 15, in order to promote an individual deformation of the latter. The material 16 of the regions 17 is preferably insulating. The material 16 of the separation region(s) 17 is preferably chosen with a low Young's modulus, which can be less than 100 GPa and in particular than 50 GPa, preferably less than 10 GPa in order to not disturb the deformation of the blocks 15 of piezoelectric material 14. Advantageously, a material 16 containing polymer, in particular an insulating polymer, for example such as 9300 series Fujifilm LTC, or TOK TELR, is chosen. There can also be regions 17 made of photosensitive polymer for example a resin of the S1800 series type or photosensitive dry films of the WBR 2000™ type.

During a test, an electric field may be applied to one or more given block(s) 15 containing piezoelectric material 14, between a shared electrode 18 belonging to the structure 10 and provided at a first end 15A of the blocks 15 and at least one conductive stud (not shown in this drawing) of the addressing circuit arranged on the side of a second end 15B of the given block(s) 15 of piezoelectric material 14, opposite to the first end 15A.

In the specific exemplary embodiment illustrated, the second end 15B of said blocks 15 ends at a “contact” face 10B against which the circuit to be tested is made to be disposed. Such an arrangement allows to place one or more blocks 15 directly in contact with a conductive stud of the circuit to be tested and to create a direct electric contact with this stud. According to one alternative (not shown), the second end 15B of the blocks 15 may be coated with conductive zones opening onto said contact face.

The shared electrode 18 of the test structure 10 is formed here by at least one conductive layer 19 arranged on and in contact with the blocks 15 of piezoelectric material 14. According to a specific exemplary embodiment, the conductive layer 19 can be in the form of a transparent conductive film for example containing a transparent conductive oxide (TCO) such as indium tin oxide (ITO), in particular when it is desired to detect the deformation of blocks 15 via an optical device. A pure zinc oxide (ZnO), or doped, in particular using one of the following elements: Al, In, Sn, B, Ga, can also be used. A pure or doped tin oxide (SnO₂), or an indium oxide (In₂O₃:H), can also be used.

The conductive layer 19 rests here on a substrate 2, preferably a flexible substrate, in other words the thickness and the composition, typically made of polymer material, of which allow it to adapt to a deformation of the blocks 15 of piezoelectric material 14. The material of the substrate 2 can be in particular made of a polymer material identical to that used to create the separation regions 17. The substrate 2 can be for example a polymer of the poly(ethylene terephthalate) (PET) type.

A material having a significant deformation under the gravitational force of its own weight is preferably chosen. The material is thus chosen with a high ratio of mass density to Young's modulus (d/E), preferably as high as possible and greater than 100 s²m⁻², typically in a range between 100 s²m⁻² and 10 ⁵s²m⁻². An organic polymer material such as PS, PET, PMMA and even more advantageously rubber can be used, as well as those usually used to implement mouldings.

Likewise, the substrate 2 can advantageously be provided made from a transparent material and in particular transparent in the range of the wavelengths at which an optical device allowing to detect a deformation of the blocks 15 operates. This optical device can be for example provided with a full-field optical interferometer (not shown) operating for example in the visible or infrared range. The tooling is associated with a light or laser source that emits an incident radiation onto said structure 10 and thus allows the analysis of its surface.

Advantageously, it is also possible to coat the blocks 15 of piezoelectric material 14 with a zone 21 that reflects light radiation, in particular in the range of the wavelengths at which the aforementioned optical device operates, for example the visible and/or infrared. This allows to improve the detection of deformation by increasing the contrast of the measurement. The reflective zone 21 arranged at the end of a block 25 can be formed by a metal, for example chosen from the following: platinum (Pt), ruthenium (Ru), titanium (Ti), nickel (Ni).

To implement a test of a matrix electronic addressing circuit 50, the structure 10 is temporarily disposed like in the exemplary embodiment illustrated in FIG. 2. The contact face 10B of the structure 10 is thus placed on and in contact with a set of conductive studs 52₁, 52₂, . . . , 52ₙ of the addressing circuit 50. In the specific example illustrated in which the blocks of piezoelectric material 14 are flush with this contact face, the blocks of piezoelectric material 14 are directly in contact with the studs 52₁, 52₂, . . . , 52ₙ.

When the spacing of distribution of the blocks 15 of piezoelectric material 14 is provided as greater than that of the conductive studs of the circuit 50, the putting in place of the structure 10 on the circuit 50 is advantageously carried out without necessarily having to carry out an alignment. The conductive studs 52₁, 52₂ of the addressing circuit are each connected here to one or more blocks 15₁, 15₂ (respectively 15₃, 15₄) of the test structure.

The addressing circuit 50 in the form for example of an ASIC can be configured to individually control the display pixels (not shown in this drawing) of a matrix. The addressing circuit 50 is itself provided with control or activation elements 54₁, 54₂. The control elements of an addressing circuit are typically each provided with one or more electronic components, for example with at least one transistor. The control or activation elements that it is desired to be able to test and preferably test individually are each provided or connected here to a conductive stud 52₁, 52₂, . . . , 52ₙ. Each conductive stud 52₁, 52₂, . . . , 52ₙ is intended here to be assembled or connected to a pixel of the matrix or to at least one layer for example a display layer that in both cases it is intended to later add onto the addressing circuit.

The conductive studs 52₁, 52₂, . . . , 52ₙ thus also have, like the control and/or activation elements 54₁, 54₂, a matrix arrangement into one or more rows of studs 52₁, 52₂, . . . , 52ₙ.

As indicated above, the addressing circuit 50 is tested here without the matrix of displays or without the display layer that it is made to control and with which it is intended to be assembled. Thus, in a specific exemplary embodiment in which the addressing circuit 50 allows to control a display device of the micro-screen type formed by a matrix of display elements of the liquid-crystal or organic LED or LED containing III-V semiconductor material type, it is verified in the functionality of the elements 54₁, 54₂, . . . , 54ₙ for control or activation of the display elements, without the matrix of display elements of the micro-screen being assembled yet.

To be able to apply test electric signals to the blocks, an arrangement is provided with, on a first side of the set of blocks 15 of piezoelectric material 14, a shared electrode 18 belonging to the structure 10, and on a second side opposite to the first side of the set of blocks 15 of piezoelectric material 14, addressing conductive studs 52₁, 52₂, . . . , 52ₙ of the control circuit to be characterised. These conductive studs 52₁, 52₂, . . . , 52ₙ form as many individual electrodes that can be controlled independently of one another.

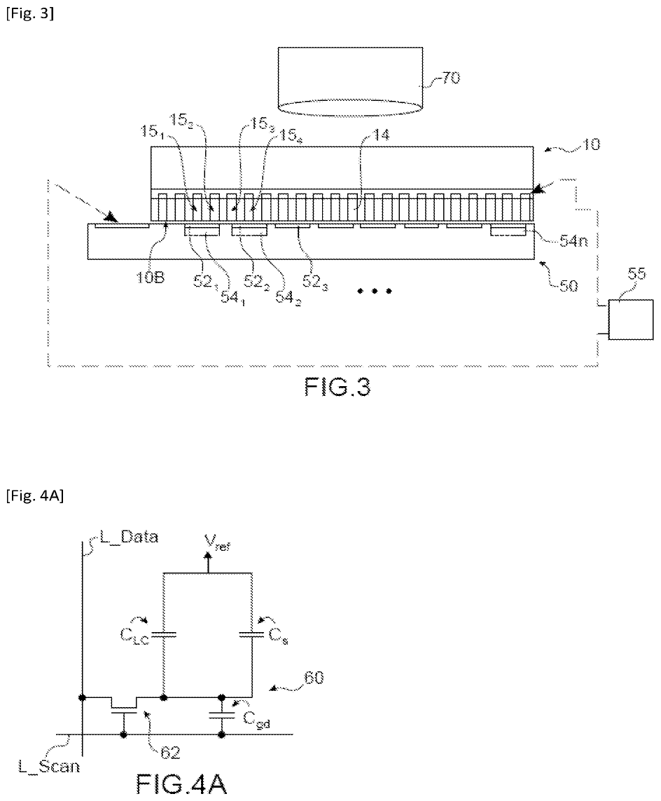

To verify the individual functionality of a control element 54₁ of the electronic circuit 50, an electric signal, typically a voltage, for example of approximately several volts, can be applied to it as an input. When this control (or activation) element is functional this can translate at the output of this control element 54₁ connected to a conductive stud 52₁ into a voltage between a first electrode formed by this conductive stud 52₁ and a second electrode 18 corresponding to the shared electrode. The test signals in particular in the form of voltages can be applied for example via a circuit 55 that generates test electric signals. Such a circuit 55 is shown schematically in the exemplary embodiment illustrated in FIG. 3.

A deformation of blocks 15₁, 15₂ of piezoelectric material 14 arranged between this first electrode 52₁ and this second electrode 18 is thus detected. Typically, when a control and/or activation element is dysfunctional, the conductive stud 52₁ of the control element is not biased or is set to a different potential and no deformation or a lesser deformation of the blocks 15₁, 15₂ of piezoelectric material 14 arranged between this first electrode 52₁ and this second electrode 18 is detected.

As mentioned above, one way to detect a localised deformation of blocks 15 of piezoelectric material 14 is to use a device provided with a profilometer, in particular a contactless profilometer, for example an optical interferometer 70 as illustrated in FIG. 3.

The interferometer 70 is placed here on the side of a face 10A of the structure 10 opposite to the contact face 10B placed against the addressing circuit 50. Such an interferometer 70 allows to obtain a map of deformation of the blocks 15 of the structure 10 translating a map of operation of the control or activation cells 54₁, . . . 54ₙ of the addressing circuit 50. Thus, by carrying out a comparison of imagery of deformation of the structure 10 before and after biasing of conductive studs, functional or non-functional zones of cells 54₁, . . . , 54ₙ of the addressing circuit 50 can be defined.

An individual control of the elements 54₁, . . . , 54ₙ of the addressing circuit 50 can be obtained and translates into a given individual biasing of each of the conductive studs 52₁, 52₂, . . . , 52ₙ.

Via the circuit 55 that generates test signals, a first test potential, for example one or several volts, can be applied to a first control element 54₁ provided with a conductive stud 52₁ in contact with one or more first blocks 15₁, 15₂ of piezoelectric material 14 then a second potential can be applied to this first element 54₁. By the inverse piezoelectric effect, these different biasings involve different deformations of the piezoelectric 14. These different deformations are measured in this example by the interferometer 70.

A test potential, equal or different than the first test potential, can also be applied to a second control element provided with a second conductive stud 52₂ in contact with one or more second piezoelectric blocks 15₃, 15₄.

The deformations of the structure 10, induced by such test electric signals, can also be detected using other detection means.

For example, as indicated above, optical detection means provided with a camera operating in the visible and/or infrared range can also be used. A technique of observation of the structure 10 via an infrared camera is in particular adapted to a material of blocks 15 of the pyroelectric type, for example containing AlN or ZnO. A detection in which the coordinates x,y in the plane of the optics of the camera of the reflected signal of an incident laser beam emitted onto the structure 10 are observed via a camera operating in the visible range can also be provided.

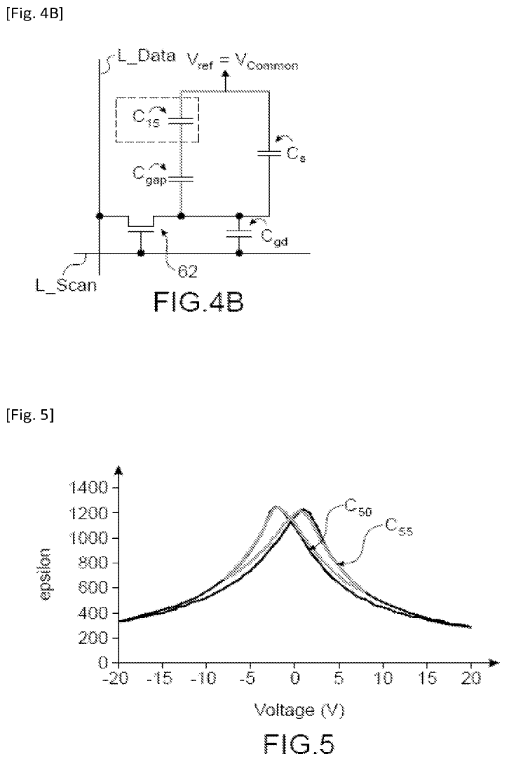

An equivalent wiring diagram of a control element 60 of the addressing circuit is given as an example in FIG. 4A, in the particular case of the addressing of a pixel of an LCD micro-screen.

The control element 60 here is a circuit provided with a transistor 62 typically using TFT (for Thin-film transistor) technology connected to addressing lines L_Scan, L_Data shared by other control elements of the matrix arrangement of the addressing circuit, a first addressing line L_Scan being used for example as a line shared by the control elements of the same horizontal row, while a second addressing line L_Data is for example a line shared by control elements of the same vertical row. A voltage of a given value is applied to a pixel via the line L_Data when the transistor 62 is activated via a signal applied on the line L_Scan.

The capacitance C_{LC} corresponds to the capacitance of a liquid-crystal display element, Cgd, representing a parasite capacitance and Cs corresponds to the capacitance of storage of the voltage during the change of a frame. The capacitances C_{LC}, Cₛ have a limit set to a reference potential.

When a test structure 10 as implemented according to the invention and described above is introduced, an equivalent diagram of a control element associated with this structure 10 is modified like in FIG. 4B.

The capacitance C_{LC} is thus replaced by capacitances in series C₁₅, Cgap. C₁₅, Cgap respectively represent: the capacitance of the blocks 15 that are connected to the control cell tested, and a parasite capacitance of the air capable of remaining between a face 50A of the ASIC on which the studs 52₁, 52₂, . . . , 52ₙ are flush and the contact face 10B of the test structure 10 on which the blocks of piezoelectric material are flush. The reference potential V_{ref} is equal here to that V_{common} of the shared electrode 18 of the test structure 10.

The capacitance of one or more given blocks 15₁ of the structure can vary according to the potentials applied at the electrodes 18, 52₁ located on either side of this given block 15₁. Thus, in addition or alternatively to a measurement of deformation of the structure 10, it is also possible to carry out one or more capacitive measurements between at least one addressing conductive stud 52₁, 52₂, . . . , 52ₙ and the shared electrode 18, for various voltages.

For example, as can be seen from the curves C₅₀ and C₅₅ of FIG. 5, which are used to illustrate a result coming from experimental data, the variation in capacitance for a block 15 of PZT material having a thickness of approximately 0.5 μm can vary by approximately 30% to 40% between the application of a first voltage of 0V and of a second voltage of approximately 5V.

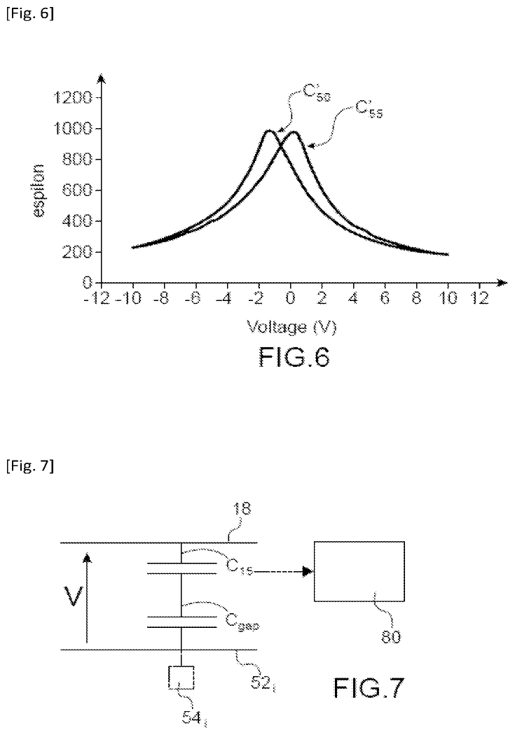

The thickness of material 14 chosen in the structure can affect this variation as shown by the example illustrated in FIG. 6. The curves C′₅₀ and C′₅₅ thus show that for a layer having the same composition, here made of PZT, but having a finer thickness, here of approximately 0.15 μm, can under the same conditions, between an applied voltage of 0V and an applied voltage of 5V, lead to a variation in capacitance of approximately 70%.

Thus, the control elements or subcells 54₁, . . . 54ₙ of a matrix addressing circuit can also be characterised by detecting a variation in capacitance value of blocks 15 of dielectric material, the dielectric properties of which are modulated according to the intensity of an electric field that is applied to them.

Here, an electric field is typically applied in the form of a voltage V between a conductive stud 52ᵢ and the shared electrode 18, this voltage V itself depending on a voltage or a test potential applied to a control cell 54ᵢ connected or provided with this conductive stud 52ᵢ.

In the exemplary embodiment illustrated in FIG. 7, the voltage V applied between the conductive stud 52i of a given subcell 54i is varied and a variation in capacitance C₁₅ of a portion of dielectric material is measured, for example using a capacitance meter 80, according to this variation.

Thus, the detection or measurement carried out using a structure as described above can, alternatively or in combination with an optical device, be carried out using electric measurement means. In the case in which the blocks are made of ferroelectric material, a variation in dipole current passing through the blocks 15 of ferroelectric material and resulting from a variation in test electric field applied onto these blocks can for example be measured.

Likewise, according to an alternative embodiment of the examples given above, a test structure can also be provided for which the blocks 15, at the ends of which a test voltage is applied, are made from a dielectric material, not necessarily piezoelectric, but the dielectric properties of which can be modulated according to the amplitude of an electric field that is applied to it. Such a material can for example be BaₓSr₍₁₋ₓ₎TiO₃ known by the acronym BST, or BCTZ (Ba(Ti_{X}Zr_{1-X})O₃—(Ba_{Y}Ca_{1-Y})TiO₃) (BCTZ).

With regard to the circuit allowing to generate the test signals mentioned above, it can be provided with at least one test stage or block integrated into the addressing circuit or in the same component or on the same chip as this addressing circuit.

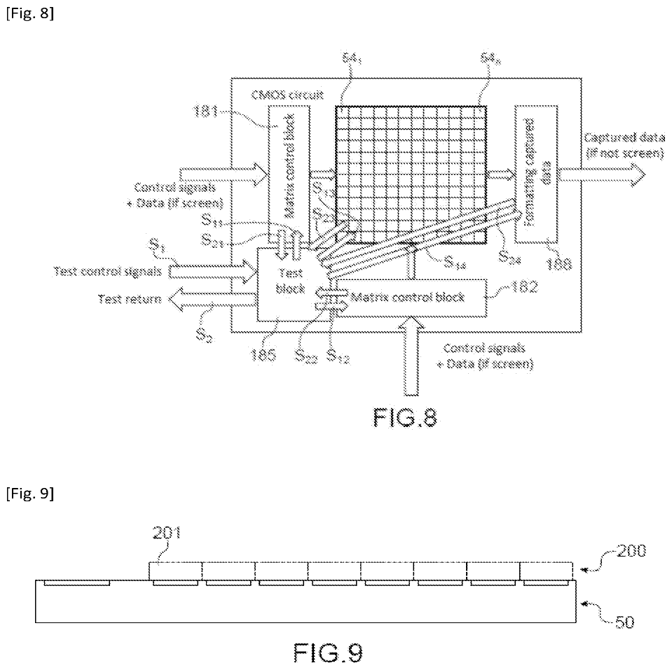

Thus, in the embodiment illustrated in FIG. 8, the addressing circuit, for example made using CMOS technology, is formed by a matrix arrangement of control elements 54₁, . . . , 54ₙ controlled via control blocks 181, 182 and integrates a test block 185 configured to emit test signals to the control blocks 181, 182. Such blocks 181, 182 allow in particular to respectively control the addressing of horizontal rows and of vertical rows of control elements 54.

The test block 185 can itself receive test control signals S₁ coming from an outside circuit, for example a logic circuit. Such signals S₁ allow in particular to trigger and/or parameterise an emission of test signals S₁₁, S₁₂ that the test block 185 emits to the control blocks 181, 182. The test block 185 can also be configured to emit return, in particular acknowledgement, signals S₂ indicating the end of testing or of a measurement phase. The signals produced by the block 185 can be of the analogue or digital type, and preferably compatible with internal blocks to be tested and with an external testing environment. The latter can for example use a protocol of the JTAG (for Joint Test Action Group) type according to the standard IEEE 1149.1.

An emission of signals S₁₃ from the test block directly to the control elements can also be implemented.

In a particular case in particular in which the addressing circuit is dedicated to the control of a type of cells other than display pixels, for example of cells made of detection elements or sensors, the test block 185 can also be configured to exchange signals S₁₄, S₂₄ with a stage 188 for formatting data captured by these pixels.

Thus, a test structure 10 as described above and a test device as described above are not limited to the implementation of test(s) and/or measurement(s) on an addressing circuit dedicated to the control of a matrix of display elements.

It is also possible to use such a test structure 10 and to implement a test device to verify the functionality of addressing circuits dedicated to the control of matrices having cells of different types.

The test structure and device can thus be applied to a circuit for addressing cells each provided with a detector element, for example for electromagnetic radiation and/or with a sensor element, for example of the MEMS type and/or with a transducer element, for example electroacoustic or electromechanical and/or with an emitter element, for example for electromagnetic or acoustic waves and/or with an actuator element, for example of the MEMS type.

Thus, according to specific exemplary embodiments, tests can be carried out on a circuit for addressing a matrix of X-ray, or infrared, image sensors, or even of pixels of a terahertz imager. Such a structure 10 can in particular be used to verify the functionality of the addressing circuit of a matrix detector containing micro-bolometers coupled with antennas.

According to another specific exemplary embodiment, it is also possible to carry out a test of functionality of an addressing circuit allowing to control a matrix of components of the MEMS (Microelectromechanical systems) or NEMS (Nanoelectromechanical systems) type, in particular a matrix of MEMS or NEMS components used for example to carry out measurements of molecular mass, or of detection of gas. According to another example, a matrix of accelerometers and/or of rate gyros using MEMS technology is tested.

According to another example, a matrix of elements that actuate micro-mirrors, in particular steerable mirrors of a DLP (for Digital Light Processing) device, can be tested.

A test structure 10 as described above and a test device using such a structure are not necessarily limited to the implementation of a functionality test in which it is verified whether or not a control and/or activation cell of a matrix circuit is functional either. Besides debugging tests, tests and/or measurements aiming to characterise and/or adjust the operation of the control cells of the addressing circuit can also be implemented.

An example of methodology in order to carry out a measurement or a test on an addressing circuit for example in the form of an ASIC can be the following.

Advantageously, first of all cleaning of the surface of the ASIC on which the conductive studs are located is carried out.

Then the test structure is disposed on the conductive studs of the matrix of the ASIC, without necessarily having to carry out an alignment.

Then the circuit that generates test signals is connected in particular to the conductive studs used to address the ASIC and to the shared electrode of the test structure.

Then a measurement of the structure is carried out using an optical device, for example a full-field interferometer, without implementing a biasing of the shared electrode and of the conductive stud(s) of the ASIC.

Then one or more measurements are carried out by emitting one or more test electric signals, in other words by carrying out a biasing of the shared electrode and of the conductive stud(s) of the ASIC.

One or more capacitive measurement(s) between addressing stud(s) and the shared electrode can be carried out first.

Then one or more measurement(s) can be carried out.

Zones of defects can thus be detected by comparing the shape of the structure to its initial shape obtained without biasing.

Measurements can also be carried out for various levels of biasing voltages.

For each level of biasing voltage an electric measurement, for example of capacitance, can thus be carried out. A measurement of deformation, for example by optical measurement, can also be carried out.

As indicated above a test structure and a test device as described above can be used during the method for manufacturing a matrix device provided with a matrix of elements, displays or detectors, or sensors, or transducers each controlled via a control cell of an electronic addressing circuit. In this case, the test device is put in place in order to test the addressing circuit before this addressing circuit is assembled and connected to the matrix of pixels or to a layer allowing to finalise the manufacturing of this matrix. FIG. 9 is used to illustrate an example of final assembly of a matrix 200 of pixels 201 on the addressing circuit 50 once a test as described above has been carried out.

A production test during the method for manufacturing a matrix device can thus be carried out using a structure described above. Thus, the addressing circuit for example using CMOS technology and manufactured by a foundry X can be tested functionally. The test can be advantageously carried out on a wafer on which several addressing circuits of the same type are created. Then, a manufacturer Y receiving this addressing circuit can, after the test carried out on the addressing circuit, carry out either the postponement or the deposition of the emitter or receiver layer or of a layer capable of modifying an incident electromagnetic radiation. The manufacturer Y thus knows all of the CMOS chips that are acceptable or not, which allows them to save time during the steps of manufacturing and especially functional verification that generally follow the assembly of the matrix and of the matrix addressing circuit.

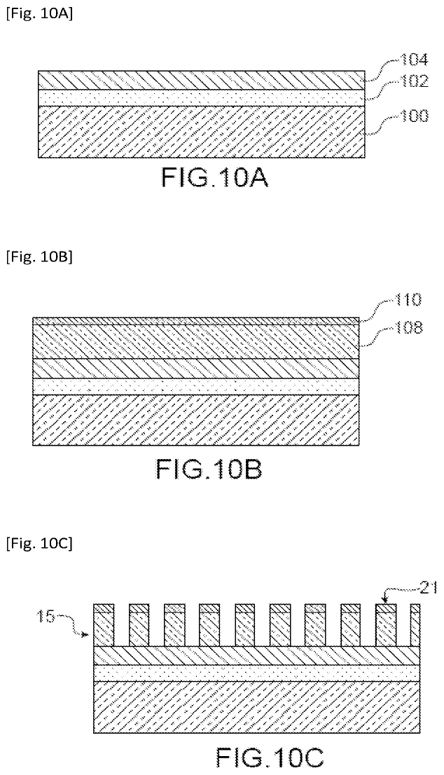

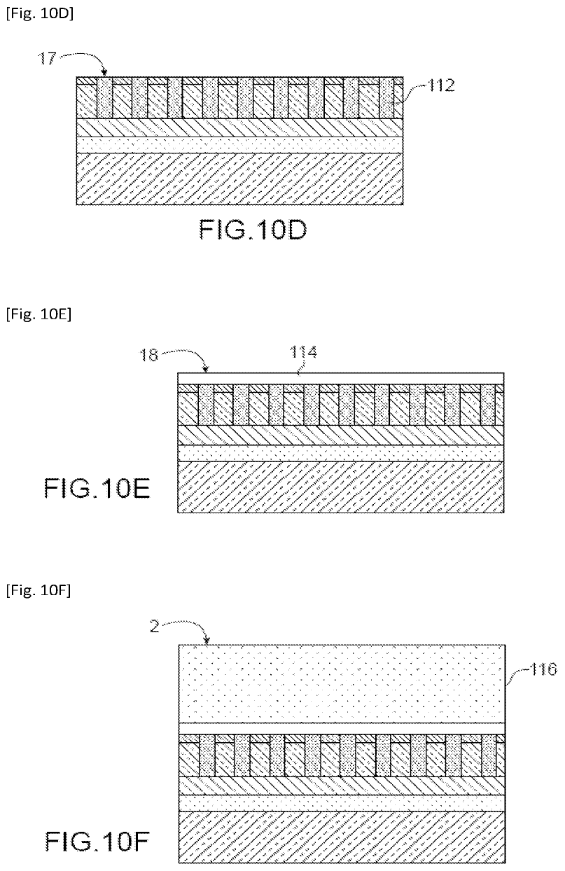

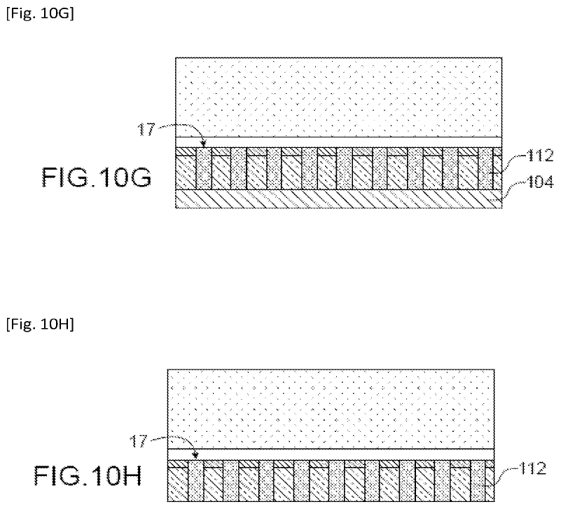

An example of a method for manufacturing a test structure as described above and in particular in relation to FIG. 1 will now be given in relation to FIGS. 10A-10H.

A starting material for this method can be a “donor” or “sacrificial” substrate 100. This donor substrate 100 is typically semiconductor and for example contains silicon. The substrate 100 can be provided with a thickness between for example 100 μm and 1 mm.

The substrate 100 is coated (FIG. 10A) with a first “separation” layer 102, having a thickness that can be between for example 1 nm and 20 μm, and with a second separation layer 104, having a thickness for example between 1 nm and 200 nm, on the first separation layer 102.

The first separation layer 102 can for example contain silicon oxide and/or silicon nitride while the second separation layer 104 can contain a noble metal for example such as silver (Ag) or gold (Au) or platinum (Pt).

The respective materials of the separation layers 102, 104 are chosen so as to create an interface with a low force of adhesion between these two separation layers 102, 104. For example, an interface formed by a layer 104 made of platinum on a layer 102 made of silicon oxide is created. The latter can be made for example by thermal oxidation of the substrate 100.

Then, the blocks 15 distributed according to a matrix arrangement are formed.

In the specific exemplary embodiment illustrated in FIG. 10B, the blocks 15 are made in a layer 108 of piezoelectric material. The piezoelectric material can be for example a ferroelectric such as lead zirconate titanate (PZT), or PZT doped with lanthanum (La) or with niobium (Nb), or PMN-PT (lead magnesium niobate-lead titanate), or KNN (potassium sodium niobate), or BNT, or BNT-BT. The piezoelectric material can also be a pyroelectric such as AlN or ZnO.

The layer 108 can have a thickness between several tens of nanometres and several micrometres, for example between 50 nm and 1 micrometre.

Then a reflective layer 110 can be made on the layer 108 of piezoelectric material. This typically metallic reflective layer 110 can be made for example from one of the following metals Pt, Ru, Ti, Ni, Au with a thickness that can be between for example 5 nm and 500 nm.

The layers 108, 110 are then structured (FIG. 10C) in order to define distinct blocks 15 of piezoelectric material distributed according to a matrix arrangement and reflective zones 21 on each of these blocks 15. Such a step can be carried out for example by photolithography in order to define a masking then etching through the openings of this masking.

An inter-block filling can then be carried out in order to form the separation regions 17. Typically the material 112 used for the inter-block filling is insulating. The filling material used, preferably provided with a low Young's modulus, is typically made of polymer. The material 112 can be for example a photosensitive resin such as that listed as WBR2050 manufactured by the company Dupont™, or a passivation polymer for example of the LTC 90xx type, or TOK TELR.

After filling, planarisation is carried out either by photo-definition or by CMP (chemical-mechanical polishing) in order to remove any deposit of separation material on the zones 21 (FIG. 10D).

To form the shared electrode 18, a conductive layer 114 is then deposited (FIG. 10E), here transparent and which can contain a transparent conductive oxide (TCO), for example containing ITO and having a thickness for example between for example 1 nm and 500 nm.

A support layer 116, for example made of polymer or made of glass, can then be deposited (FIG. 10F) in order to form the substrate 2, preferably a flexible substrate.

Then, a separation of the donor substrate is carried out by carrying out a fracturing between the separation layers 102, 104 (FIG. 10G). This can be carried out for example by inserting a blade between the two layers 102, 104.

Then the second separation layer 104 is removed (FIG. 10H) for example by etching using a chemical solution such as an HCl/HNO₃ mixture.

1. A structure for the testing of an electronic circuit for addressing a matrix of cells, said electronic addressing circuit being intended to be assembled with and connected to said matrix or at least one layer of said matrix via conductive studs, said structure comprising:
a plurality of blocks containing at least one first material, piezoelectric and/or dielectric, the dielectric properties of which can be modulated according to the intensity of an electric field that is applied to it, said blocks having a first end and a second end, the second end being opposite to the first end and ending at a contact face of said structure or a conductive zone ending at said contact face, the second end of said blocks being capable of being connected to at least one given conductive stud out of a set of conductive studs of an electronic addressing circuit,
at least one separation region between said blocks, said at least one separation region containing at least one insulating material, said test structure further comprising:
a shared electrode connected to the first end of said blocks containing said first material.

2. The structure according to claim 1, wherein the shared electrode rests on a substrate, with a ratio of mass density to Young's modulus greater than 100 s²m⁻², in particular made of a polymer material or made of rubber.

3. The structure according to claim 1, wherein the shared electrode rests on a substrate containing a transparent material.

4. The structure according to claim 1, wherein the shared electrode is formed by a transparent conductive layer.

5. The structure according to claim 1, wherein said first end of said blocks containing said first material is coated with a conductive and reflective zone.

6. The structure according to claim 1, wherein said insulating material contains polymer material and/or has a Young's modulus of less than 100 GPa, advantageously less than 50 GPa.

7. A test device for an electronic circuit for addressing a matrix of cells, comprising:
the electronic addressing circuit, each cell being capable of being controlled via a control element of said electronic addressing circuit, said electronic addressing circuit being provided with a matrix set of control elements and having a matrix arrangement of conductive studs, each control element being provided with at least one of said conductive studs, the test device further comprising:
a structure according to claim 1, said structure being arranged in a removable manner on said addressing circuit and so that at least a first conductive stud out of said conductive studs is connected to one or more blocks containing the first material of said structure, and at least a second conductive stud out of said conductive studs is connected to one or more other blocks containing the first material of said structure.

8. The test device according to claim 7, wherein in said matrix set, said conductive studs of the addressing circuit are distributed according to a first distribution spacing and wherein the blocks containing said first material are distributed according to another matrix set with a second distribution spacing, the second distribution spacing being provided as greater than the first distribution spacing and so that each conductive stud is connected to at least one block containing the first material of said structure.

9. The test device according to claim 7, further comprising: a circuit that generates test electric signals, said generator circuit being connected to said shared electrode and configured to apply one or more test electric signals to said control elements of said addressing circuit.

10. The test device according to claim 9, wherein said first material is piezoelectric, further comprising a measurement device, in particular provided with a contactless interferometer and/or with optical measurement means provided with a camera, the measurement device being configured to detect a deformation of said structure after at least one first test electric signal is applied to a first control element.

11. The test device according to claim 9, further comprising an electric measurement device connected to the shared electrode and to at least a first stud out of said conductive studs, the electric measurement device being configured to measure a response electric signal to at least one first test electric signal applied to a first control element connected to the first stud,
the electric measurement device being in particular provided with a capacitance meter configured to, after the first test electric signal has been applied, measure a capacitance between said first stud and said electrode and/or with a means for measuring current between said first stud and said electrode after the first test electric signal has been applied.

12. The test device according to claim 9, wherein said circuit that generates test signals is configured to:
apply a first potential to a first control element of the addressing circuit, then apply another potential different from the first potential to the first control element, and/or to
apply a first potential to a first control element of the addressing circuit and apply a second potential to a second control element of the addressing circuit.

13. The test device according to claim 7, wherein said cells are each provided with a display element, or detector, or sensor, or transducer, or emitter, or actuator.

14. The test device according to claim 7, wherein the electronic addressing circuit is dedicated to controlling a matrix of cells each provided with an LCD or organic LED or micro-LED display element, in particular made of a III-N material such as GaN.

15. A method for manufacturing a matrix device provided with a matrix of cells, each cell being capable of being controlled via a control element of an electronic addressing circuit, the method comprising, in this order, steps involving:
putting in place a test device according to claim 7, to test the addressing circuit,
removing said test structure from said addressing circuit, then
assembling and connecting said matrix of cells or at least one layer, in particular for display, onto said addressing circuit.
